(19) United States
(12) Patent Application Publication
(10) Pub. No.: US 2019/0237503 A1
(43) Pub. Date: Aug. 1, 2019

(54) Image Sensor, and Forming Method thereof, and Working Method Thereof

(71) Applicant: Huaian Imaging Device Manufacturer Corporation, Huaian (CN)

(72) Inventors: Amane OISHI, Huaian (CN); Xiaolu HUANG, Huaian (CN)

(21) Appl. No.: 16/054,900

(22) Filed: Aug. 3, 2018

(30) Foreign Application Priority Data
Jan. 30, 2018 (CN) 201810090965.2

(51) Int. Cl. H01L 27/146

(52) U.S. Cl. CPC H01L 27/14643; H01L 27/1464; H01L 27/14616; H01L 27/14689

(57) ABSTRACT

The present disclosure provides an image sensor, and a forming method and a working method thereof. The image sensor includes: a substrate, provided with a well region part of the well region having a photoelectric doped region, the well region including a second region, a first region and a third region located on two sides of the second region, the first region and the third region being adjacent to the two sides of the second region respectively; a first gate structure, located on a surface of the second region of the well region; a second gate structure, located on a surface of the first region of the well region; and a floating diffusion region, located in the third region of the well region, the floating diffusion region being adjacent to the first gate structure. The image sensor can reduce an image lag while increasing the full well capacity.

### CROSS REFERENCES TO RELATED APPLICATIONS

This application claims the benefit of priority to Chinese Patent Application No. CN201810090965.2, entitled “Image Sensor, and Forming Method thereof, and Working Method thereof”, filed with SIPO on Jan. 30, 2018, the contents of which are incorporated herein by reference in its entirety.

### TECHNICAL FIELD

The present disclosure relates to the technical field of semiconductor devices, and in particular, to semiconductor photoelectric image sensors.

### BACKGROUND

Image sensors are semiconductor devices converting optical images into electronic digital images. Image sensors have many varieties including charge coupled devices (CCD) and CMOS image sensors.

Although a charge coupled device (CCD) is good in imaging quality, a small number of manufacturers are able to make them due to a complex manufacturing process, thereby resulting in high manufacturing cost. In particular, a large CCD has a complex drive mode, high energy consumption and a multi-stage photographic process, making it expensive.

Because of low energy consumption and relatively fewer photography process steps, a CMOS image sensor has relatively simple manufacturing processes. Moreover, a CMOS image sensor allows a control circuit, a signal processing circuit and an analog-to-digital converter to be integrated on a chip, it is applicable to products of all sizes and is widely applied to various fields.

However, the gate channel 103 cannot open completely and quickly during subsequent electron transmission phase, resulting in partial electron transmit into the floating diffusion region 102. That is when an image lag occurs. There is a need to eliminate the image lag in a CMOS image sensor.

### SUMMARY

The present disclosure provides an image sensor, and its operation method.

An image sensor comprising: a substrate having a front surface to receive light and a back surface opposite to the front surface; a well region doped with a first type of ions provided in the back surface of the substrate; a first region, a second region, and a third region sequentially disposed in the well region, wherein the first and third regions are on two sides of the second region; a photoelectric region doped with a second type of ions disposed in the first region; a first gate structure located on the back surface of the substrate aligned with the second region; a second gate structure, located on the back surface of the substrate aligned with first region; and a floating diffusion region located in the third region and next to the first gate structure.

Optionally, the floating diffusion region is doped with a third type of ions; wherein the first and third types of dopants have opposite conductive types, and wherein the first and second types of dopants have opposite conductive signs.

The present disclosure also provides a method of forming an image sensor, comprising: providing a substrate having a front surface receiving light and a back surface; doping a well region in the substrate; forming a first region, a second region, and a third region sequentially in the well region, wherein the first and third regions are set on two sides of the second region; preparing a doped photoelectric region partially overlapping the first region; forming a first gate structure on the back surface of the substrate aligned with the second region of the well region; forming a second gate structure on the back surface of the substrate aligned with the first region of the well region; and forming a floating diffusion region on the back surface of the substrate in the third region wherein the floating diffusion region is next to the first gate structure and away from the photoelectric region.

Optionally, forming the first gate structure and the second gate structure comprises: forming a gate dielectric film on the back surface of the substrate; forming a gate film on the gate dielectric film, wherein the gate film comprises a first mask layer patterned to form the first and second gate structures and the exposed floating diffusion region; and forming a diffusion region.

Optionally, a first type of doped ions are provided in the well region; a second doped type of ions are provided in the photoelectric doped region, the second type of doped ions and the first type of doped ion are opposite in conduction types; and a third type of doped ions are provided in the floating diffusion region, the third type of doped ions and the first type of doped ions are opposite in conduction types.

The present disclosure further provides an image sensor, comprising: a bias voltage; a first and a second gate channels at the bottom of a first gate structure and a second gate structure, wherein the gate channel is closed when an incident light enters the photoelectric diode and photo-electrons are generated; and wherein the first and second gate channels at the bottoms of the first gate structure and the second gate structure open, and execute a reading operation, wherein the electrons are transmitted via the first gate structure into the floating diffusion region.

Optionally, the well region has a P type doping, and the photoelectric doped region and the floating diffusion region have an N type doping.

Optionally, the first and second gate channels are closed before transmitting photo-electrons, wherein the bias voltage is 0 volt at the second gate structure.

### BRIEF DESCRIPTION OF THE DRAWINGS

FIG. 1 is a schematic diagram of an image sensor according to an embodiment of the current disclosure.

FIG. 2 and FIG. 3 are schematics of an image sensor's potential states during its operation according to an embodiment of the current disclosure.

FIG. 4 to FIG. 6 shows steps of forming an image sensor according to an embodiment of the current disclosure.

FIG. 7 and FIG. 8 are schematics of an image sensor's potential states during its functioning according to another embodiment of the current disclosure.

### DETAILED DESCRIPTION OF THE PREFERRED EMBODIMENTS

The foregoing objectives, features, and advantages of the present disclosure will become more apparent from the following detailed description of specific embodiments of the disclosure in conjunction with the accompanying drawings. In the detailed description of the embodiments of the present disclosure, for convenience of description, the schematic diagram will be partially enlarged not according to an ordinary ratio, and the schematic diagram is only an example, which should not limit the protection scope of the present disclosure. In addition, three-dimensional space dimensions of length, width, and depth should be comprised in actual production.

Just as described in the related arts, the performance of an existing image sensor needs to improve.

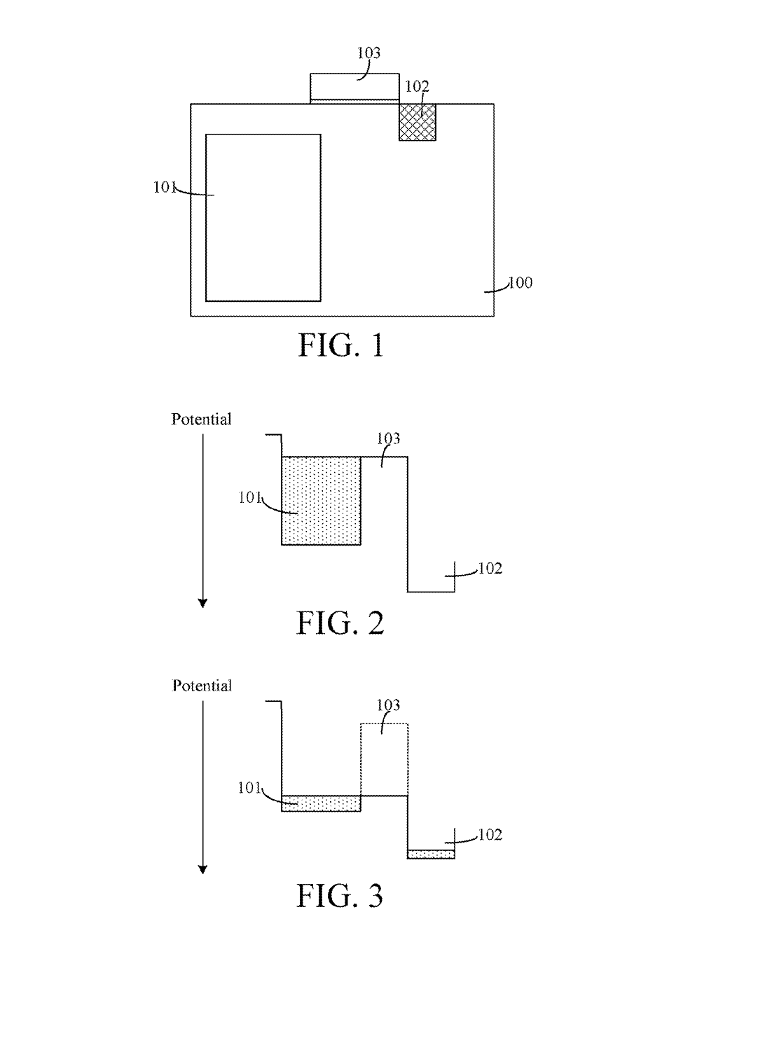

FIG. 1 is a schematic diagram of an image sensor according to an embodiment of the current disclosure.

Referring to FIG. 1, The image sensor includes a substrate 100, provided with a well region (not shown in the figure); a gate structure 103 located on a surface overlaying the well region; and a photoelectric doped region 101 and a diffusion region 102 located on two sides of the gate structure 103 in the well regions.

The foregoing image sensor is a CMOS image sensor, a first ionic doped region is provided in the well region, and a second doped ionic region is provided in the photoelectric doping region 101. The second doped ionic region and the first doped ionic region have opposite conductive types. A photodiode is formed between the photoelectric doping region 101 and the well region, so electrons generated by photons can be moved out of photoelectric region. Ions in the floating diffusion region 102 recombine with the electrons generated by the photodiode and photoelectric voltage is produced. The gate structure 103 keeps a bias just to transfer the electrons generated by the photodiode to the floating diffusion region 102.

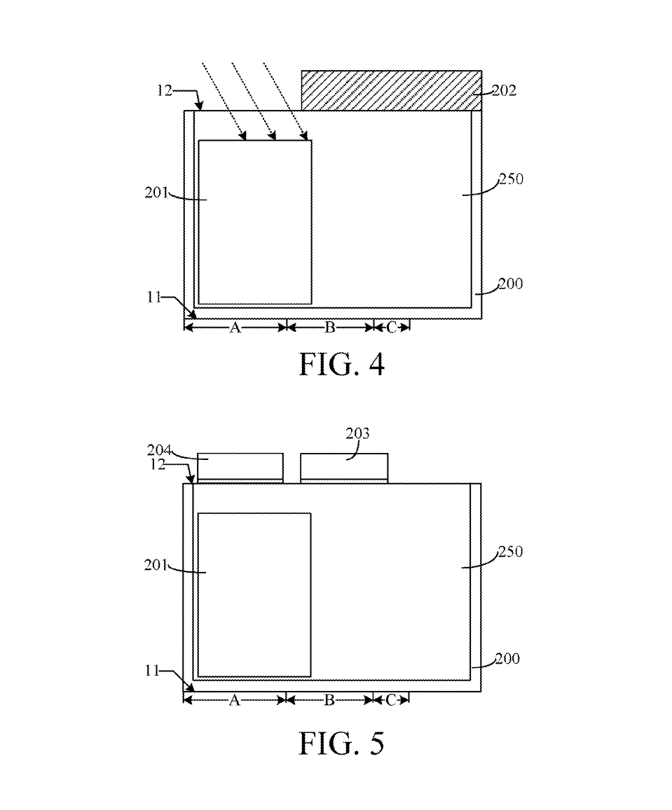

Referring to FIG. 2, FIG. 2 shows an image sensor's potential states before transmission of electrons in a photodiode. A gate channel under gate structure 103 is closed, electrons generated by the photodiode after absorbing photons are stored in the photodiode. Wherein in the figures, the potential arrow indicates that the potential going from high to low.

The way it is written here is dangerous for the validity of the patent in the future, even if it is granted someday.

The maximum number of charges generated in a photodiode in a doped area or well is referred to as a full well capacity (FWC). As one critical parameter, the larger the full well capacity is, the better off the performance of the image sensor becomes. A method for increasing the full well capacity is increasing a potential difference between top and bottom surfaces of a photodiode.

Referring to FIG. 3, FIG. 3 shows an image sensor's potential states in transmission of electrons in a photodiode. The gate channel under the gate structure 103 is opened, and the gate structure 103 transmits electrons into the floating diffusion region 102.

In order to improve the full well capacity (FWC) of the photodiode, a potential gap between top and bottom edges of the photodiode is increased, making the bottom potential of the photodiode lower.

However, if the bottom potential of the photodiode is lower, the gate channel kept at negative bias at the bottom of the gate structure 103 cannot open completely and quickly during subsequent electron transmission phase, resulting in partial electron transmit into the floating diffusion region 102. That is when an image lag occurs.

To solve the image lag problem, the present disclosure provides a forming method of an image sensor, including: forming a second gate structure on a surface of a first region of a substrate; and forming a first gate structure on a surface of a second region of the substrate.

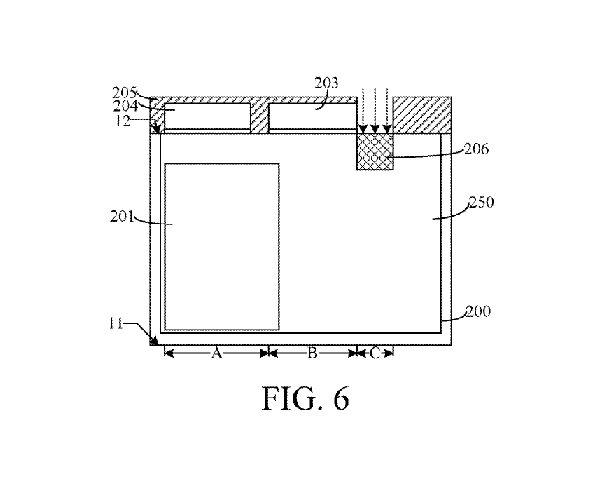

FIG. 4 to FIG. 6 shows steps of forming an image sensor according to an embodiment of the current disclosure.

Referring to FIG. 4, a substrate 200 is provided, wherein a well region 250 is provided in the substrate 200, part of the well region 250 has a doped photoelectric region 201. The substrate 200 comprises a first region A, a second region Band a third region C, the first region A and the third region C are on the two sides of the second region B respectively.

A first ion doped region is provided in the well region 250.

In the present embodiment, the first doped region is P-type.

In another embodiment, the first doped region may be an N-type.

In the present embodiment, the substrate 200 is made from silicon.

In other embodiments, the substrate is made from germanium, silicon germanium, silicon on an insulator, or germanium on an insulator.

A method of forming the photoelectric doped region 201 includes patterning a first photoresist 202 on surfaces partially overlays the second region B and the third region C of the substrate 200; and ion implant doping the photoelectric region 201, which partially over lays the first region A of the substrate 200 by taking the first photoresist 202 as a mask.

The first photoresist 202 is used to protect the second region B and the third region C of the substrate 200, to prevent ion beams from also doping the second region B and the third region C of the substrate 200.

A process of forming the photoelectric doping region 201 includes a first ion implantation process, which has included a second type of ions in the ion beam. The second type of ions in 201 and the first type of ions in the well region 250 have opposite conduction types. Therefore, a photodiode is formed between the photoelectric doped region 201 and the well region 250, the photodiode is used to absorb photons and convert them to electrons.

In the present embodiment, the second doped ions have N-type such as phosphorus ions or arsenic ions.

In other embodiments, the second doped ions have P-type such as boron ions or BF₂⁺ ions.

The surface of the first region A of the substrate 200 overlays a second gate structure, the surface of the second region B of the substrate 200 is used to subsequently align to the first gate structure, and the surface of the third region C aligns to the diffusion region. The first region A and the third region C are set at two sides of the second region B respectively, and the second region B enables electrons in the photodiode to pass through the first gate structure and reach the diffusion region 206.

The substrate 200 has an illumination face 11 and a non-illumination face 12, opposite to each other. The illumination face 11 is illuminated with incident image light, and the photodiode absorbs photons in the incident light and generate photo-electrons. The non-illumination face 12 sits in the back and does not receive the incident light.

In the present embodiment, the image sensor is a back-side-illumination (BSI) image sensor. In other embodiments, the image sensor is a front-side-illumination (FSI) image sensor.

Referring to FIG. 5, a first gate structure 203 is formed on a surface of the second region B of the well region 250, and a second gate structure 204 is formed on a surface of the first region A of the well region 250.

The forming method further includes: etching over the photoresist in a lithographic process and removing the first photoresist 202 after patterning the first gate structure 203.

The process of removing the first photoresist 202 comprises: an ashing process.

In the present embodiment, the first gate structure 203 and the second gate structure 204 are formed at the same time; and a method for forming the first gate structure 203 and the second gate structure 204 comprises: forming a gate dielectric film on surfaces the first region A, the second region B and the third region C of the substrate 200, and forming a gate film on a surface of the gate dielectric film; forming a first mask layer (not shown in the figure) on a top surface of the gate film, the first mask layer covers the surface of the gate film of the first region A and the second region B partially; and etching the gate film and the gate dielectric film by taking the first mask layer as a mask, forming a first gate structure 203 on a surface of the second region B of the well region 250, and forming a second gate structure 204 on a surface of the first region A of the well region 250.

The first gate structure 203 comprises a first gate dielectric layer (not shown in the figure) and a first gate layer located on a surface of the first gate dielectric layer.

The second gate structure 204 comprises a second gate dielectric layer (not shown in the figure) and a second gate layer located on a surface of the second gate dielectric layer.

The material of the gate dielectric film comprises silicon oxide, and correspondingly, materials of the first gate dielectric layer and the second gate dielectric layer comprise: silicon oxide. A process of forming the gate dielectric film comprises: a chemical vapor deposition (CVD) processor a physical vapor (PVD) deposition process.

A material of the gate film can be silicon, and correspondingly, materials of the first gate layer and the second gate layer include silicon. A process of forming the gate film comprises: a chemical vapor deposition (CVD) process or a physical vapor deposition (PVD) process.

Materials of the first mask layer include silicon nitride or titanium oxide. The first mask layer is used to form masks of the first gate dielectric layer, the second gate dielectric layer, the first gate layer, and the second gate layer.

A process of etching the gate film and the gate dielectric film by applying the first mask layer includes: one or a combination of a dry etching process and a wet etching process.

The first gate structure 203 is used to transmit electrons generated by the photodiode into the floating diffusion region 206.

Referring to FIG. 6, a floating diffusion region 206 is formed in the third region C of the well region 250.

The increase of potential difference between the top and the bottom of the photodiode region is conducive to increasing the full well capacity. Although the bottom potential of the photodiode is pushed low by a larger potential difference required between the top and bottom of the photodiode, applying a negative bias voltage to the second gate structure 204 in a subsequent reading process of the image sensor can increase the bottom potential of the photodiode, such that the bottom potential of the photodiode is higher than the bottom potential of the first gate structure 203. Under this additional bias, the gate channel at the bottom of the first gate structure 203 can be opened more quickly and more completely. As a result, higher percentage photoelectrons are transmitted enables fuller into the floating diffusion region through the first gate structure 203. When the FWC is increased, the image lag is reduced.

Referring to FIG. 6, showing a method for forming the floating diffusion region 206 including: forming a second photoresist 205 covering the first gate structure 203 and the second gate structure 204, including top and side surface. The second photoresist 205 aligned to the third region C of the substrate 200; and the floating diffusion region 206 is exposed and formed in the well region 250 masked by the second photoresist 205.

The second photoresist 205 protects the top and partial sidewalls of the first gate structure 203, parts of the surface of the substrate 200, and the top and the sidewalls of the second gate structure 204.

A process of forming a floating diffusion region 206 in the well region 250 by taking the second photoresist 205 as a mask comprises a second ion implantation process, in this process a third type of doped ions are applied, the third and the first doped ions have opposite charge polarities.

In the present embodiment, the third doped ions are N-type including a phosphorus ions or arsenic ions.

In other embodiments, the third doped ions are P-type ions such as boron ions or BF₂±ions.

The floating diffusion region 206 stores electrons generated by the photodiode.

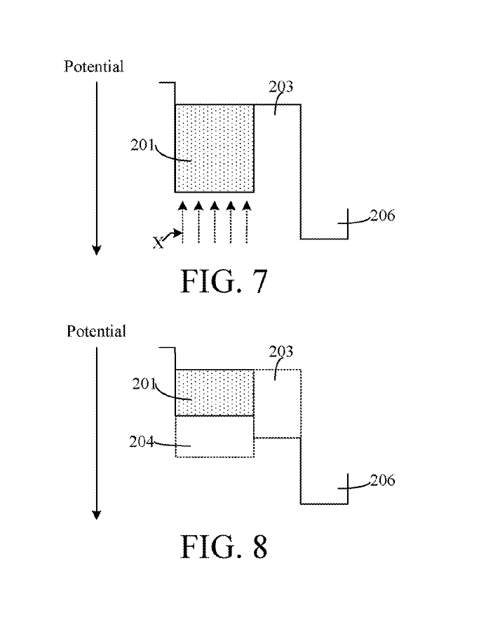

FIG. 7 and FIG. 8 are schematics of an image sensor's potential states during its functioning according to another embodiment of the current disclosure.

Now refer to FIG. 7, which shows an image sensor's potential states before transmission of electrons in a photodiode.

Incident light X comes to an illumination face 11 (as shown in FIG. 4), at the bottom of the substrate. The gate channels at the bottoms of the first gate structure 203 and the second gate structure 204 are closed. The photodiode in the photoelectric doped region 201 and the well region 250 absorbs the incident light X and generates photo-electrons.

The step of closing the channels at the bottoms of the first gate structure 203 and the second gate structure 204 includes applying a voltage of 0 volt to the top of the second gate structure 204. The percentage of photo-electrons in the photodiode reaches the full well capacity. In order to increase the full well capacity, a potential difference between top and bottom of the photodiode 201 is increased.

Referring to FIG. 8, which shows an image sensor's potential states in transmission of electrons in a photodiode. The gate channels at the bottoms of the first gate structure 203 and the second gate structure 204 are opened, and a reading operation is executed, such that the photo-electrons are transmitted into the floating diffusion region 206 via the first gate structure 203.

The step of opening the channels at the bottoms of the first gate structure 203 and the second gate structure 204 includes applying a negative bias voltage to the second gate structure 204.

Increasing a potential difference between top and bottom of the photodiode leads to increasing the full well capacity (FWC) of the photodiode. Although the bottom potential of the photodiode is pushed lower by a larger potential gap of the photodiode, applying of a negative bias voltage to the top of the second gate structure 204 in a reading process of the image sensor can increase the bottom potential of the photodiode, such that the bottom potential of the photodiode turns higher than the bottom potential of the first gate structure 203, and the channel at the bottom of the first gate structure 203 can be opened quicker and fuller, thereby enables higher percentage of photo-electrons from the photodiode pass through the first gate structure 203 and reach to the floating diffusion region 206. As a result, the image lag is reduced significantly.

The present disclosure also provides an image sensor made by the disclosed forming method may include:

a substrate 200, a well region 250 is provided in the substrate 200, part of the well region 250 has a photoelectric doped region 201, the substrate 200 comprises a second region B, and a first region A and a third region C locate on two sides of the second region B, and the first region A and the third region C locate on the two sides of the second region B respectively;

a first gate structure 203 locates on a surface of the second region B of the well region 250;

a second gate structure 204 located on a surface of the first region A of the well region 250; and

a floating diffusion region 206 located in the third region C of the well region 250, the floating diffusion region 206 is at one side of the first gate structure 203, opposite to the photodiode 201.

The first doped ions are provided in the well region 250; second doped ions are provided in the photoelectric doping region 201, the second doped ions are the first doped ions have opposite conduction types; and a third doping ion is provided in the floating diffusion region 206, the third doping ion and the first doping ion has opposite conduction types.

The substrate 200 comprises an illumination face 11 and a non-illumination face 12, opposite to each other, the first gate structure 203 and the second gate structure 204 are located on a surface of the non-illumination face 12 of the substrate 200.

The present disclosure have the following benefits:

In the image sensor provided by the present disclosure, a photoelectric doped region and a well region form a photodiode. In an accumulation process, the increase of a difference between top and bottom potentials of the photodiode is conducive to the increase of the full well capacity of the photodiode. Although the bottom potential of the photodiode is lower due to the increase of the difference between the top and bottom potentials of the photodiode, since a second gate structure is provided on a surface of a first region of the well region in a reading process of the image sensor, applying of a negative bias voltage to the second gate structure can increase the bottom potential of the photodiode, such that the bottom potential of the photodiode is higher than the potential of a first gate structure, thereby being more conducive to transmission of electrons in the photodiode into a floating diffusion region via the first gate structure, and also conducive to reduction of an image lag. Therefore, the image sensor can also reduce the image lag while increasing the full well capacity of the photodiode.

Although the present disclosure is disclosed as above, it is not limited. Any person skilled in the art may make various variations and modifications without departing from the spirit and scope of the present disclosure. Therefore, the scope of protection of the present disclosure should be determined by the scope defined by the claims.

What is claimed is:

1. An image sensor, comprising:
a substrate having a front surface to receive light and a back surface opposite to the front surface;
a well region, doped with a first type of ions, provided in the back surface of the substrate;
a first region, a second region, and a third region sequentially disposed in the well region, wherein the first and third regions are on two sides of the second region;
a photoelectric region doped with a second type of ions disposed in the first region;
a first gate structure located on the back surface of the substrate aligned with the second region;
a second gate structure, located on the back surface of the substrate aligned with first region; and
a floating diffusion region located in the third region and next to the first gate structure.

2. The image sensor according to claim 1, wherein the floating diffusion region is doped with a third type of ions; wherein the first and third types of dopants have opposite conductive types, and wherein the first and second types of dopants have opposite conductive signs.

3. The image sensor according to claim 1, wherein an illumination face is on the front surface of the substrate, and wherein the first gate structure and the second gate structure are located on the surface of the non-illumination face on the back surface of the substrate.

4. A method of forming an image sensor, comprising:
providing a substrate having a front surface receiving light and a back surface;
doping a well region in the substrate;
forming a first region, a second region, and a third region sequentially in the well region, wherein the first and third regions are set on two sides of the second region;
preparing a doped photoelectric region partially overlapping the first region;
forming a first gate structure on the back surface of the substrate aligned with the second region of the well region;
forming a second gate structure on the back surface of the substrate aligned with the first region of the well region; and
forming a floating diffusion region on the back surface of the substrate in the third region wherein the floating diffusion region is next to the first gate structure and away from the photoelectric region.

5. The method of forming an image sensor according to claim 4, wherein forming the first gate structure and the second gate structure comprises:
forming a gate dielectric film on the back surface of the substrate;
forming a gate film on the gate dielectric film, wherein the gate film comprises a first mask layer patterned to form the first and second gate structures and the exposed floating diffusion region; and
forming a diffusion region.

6. The method of forming an image sensor according to claim 4, wherein a first type of doped ions are provided in the well region; a second doped type of ions are provided in the photoelectric doped region, the second type of doped ions and the first type of doped ion are opposite in conduction types; and a third type of doped ions are provided in the floating diffusion region, the third type of doped ions and the first type of doped ions are opposite in conduction types.

7. An image sensor according to claim 1, further comprising:
a bias voltage;
a first and a second gate channels at the bottom of a first gate structure and a second gate structure, wherein the gate channel is closed when an incident light enters the photoelectric diode and photo-electrons are generated; and wherein the first and second gate channels at the bottoms of the first gate structure and the second gate structure open, and execute a reading operation, wherein the electrons are transmitted via the first gate structure into the floating diffusion region.

8. An image sensor according to claim 6, wherein the well region has a P type doping, and the photoelectric doped region and the floating diffusion region have an N type doping.

9. The method of an image sensor according to claim 6, wherein the first and second gate channels are closed before transmitting photo-electrons, wherein the bias voltage is 0 volt at the second gate structure.

10. An image sensor according to claim 6, wherein the first and second gate channels are open when transmitting photo-electrons, wherein the bias voltage is negative on the second gate structure.
